(19) United States
(12) Patent Application Publication
(10) Pub. No.: US 2015/0180463 A1
(43) Pub. Date: Jun. 25, 2015

(54) MONITORING METHOD AND DEVICE FOR POWER SEMICONDUCTOR SWITCH

(71) Applicant: ABB OY, Helsinki (FI)

(72) Inventor: Lauri PELTONEN, Helsinki (FI)

(73) Assignee: ABB OY, Helsinki (FI)

(21) Appl. No.: 14/565,153

(22) Filed: Dec. 9, 2014

(30) Foreign Application Priority Data
Dec. 23, 2013 (EP) 13199270.3

(51) Int. Cl. H03K 17/082; G01R 31/28; G01R 31/327; H02M 1/08

(52) U.S. Cl. CPC H03K 17/0828; H02M 1/08; G01R 31/2851; G01R 31/327; H02M 2001/0054

(57) ABSTRACT

An exemplary power semiconductor switch is configured to be controlled on the basis of a gate voltage signal driven by a gate driver unit. The device includes a measuring component for generating a saturation voltage signal on the basis of a voltage over the power semiconductor switch, and an auxiliary switch connected between a saturation voltage signal line carrying the saturation voltage signal and an output of the gate driver unit driving the gate voltage signal. The auxiliary switch is configured to be controlled to a conductive state or a non-conductive state on the basis of the gate voltage signal. A feedback component is provided for generating a saturation feedback signal on the basis of the saturation voltage signal.

### RELATED APPLICATION(S)

This application claims priority under 35 U.S.C. §119 to European application No. 13199270.3 filed in Europe on Dec. 23, 2013, the content of which is hereby incorporated by reference in its entirety.

### FIELD

The present disclosure relates to monitoring operation of a power semiconductor switch, and particularly to monitoring supply voltages of a gate driver controlling the switch.

### BACKGROUND INFORMATION

In an inverter or a frequency converter, power semiconductor switches can be controlled to one of two operational states: a conductive state (e.g., an on-state) or a non-conductive state (e.g., an off-state). In simplified terms, current flows through the switch in the conductive state and a voltage over the switch is near to zero. In the non-conducting state, the switch does not conduct current, and the voltage over the switch is at a higher level. For example, in the case of an inverter, the voltage over a switch in the non-conducting state can be the whole voltage (or half of the voltage) of the DC link of the inverter. Power semiconductor switches can be IGBTs or MOSFETs, for example.

Gate drivers can be used for turning the switches on or off. A gate driver can use a positive voltage for turning a power semiconductor switch on and a negative voltage for turning the switch off. By using a negative turn-off voltage, spurious turn-ons of the switch in the event of voltage spikes on the gate of the switch can be prevented. The supply voltages can be provided by an isolated power supply.

Detecting short circuit conditions can be important in some applications using power semiconductor switches. For example, fast and reliable short circuit detection can be desirable to avoid permanent damage to a switch and/or the related circuitry.

In order to detect a short circuit, a saturation voltage of a switch can be measured. The saturation voltage can be represented by a collector-emitter voltage of an IGBT, for example. It can be enough to know whether the voltage is above or below a certain limit. The saturation voltage can be compared with a positive voltage of the gate driver's supply, for example.

In order to avoid false short circuit faults during a switching event, the short circuit detection can include a small delay which prevents reading of the saturation input before IGBT has switched on completely.

FIGS. 1a and 1b show exemplary waveforms of short circuit detection based on a measurement of a collector-emitter voltage v_{CE} in accordance with known inplementations. FIG. 1a shows the waveforms during normal operation. A gate voltage v_{G} is used to control a semiconductor switch. At instant t₁, the gate voltage switches from −15 V to 15 V, and the switch turns on. The collector-emitter voltage v_{CE}, drops to a near-zero value. A two-level saturation feedback v_{fb} signal is generated by comparing the collector-emitter voltage v_{CE} to a set detection limit, in this case 15 V. The collector-emitter voltage v_{CE} is lower that the limit, and thus the saturation feedback v_{fb} is set to a high level which in this case is 5 V.

At instant t₂ in FIG. 1a, the gate voltage switches back to −15 V. The switch turns off, and the collector-emitter voltage v_{CE} rises above the set limit. After a small delay, the saturation feedback signal v_{fb} is set to a low level which in this case is 0 V.

FIG. 1 b shows waveforms during a short circuit. Again, at instant t₁, the gate voltage switches from −15 V to 15 V, the switch turns on, and the collector-emitter voltage v_{CE} drops to a near-zero value. The collector-emitter voltage v_{CE} is lower that the detection limit and is set to the high level. However, instead of remaining near zero, the collector-emitter voltage v_{CE} starts to rise again as a large short circuit current starts to flow through the switch. The collector-emitter voltage v_{CE} exceeds the detection limit and, after a small delay, the saturation feedback signal v_{fb} is set again to the low level.

At instant t₂ in FIG. 1 b, the gate voltage switches back to −15 V. The switch turns off, and the collector-emitter voltage v_{CE} rises to the high, non-conductive state level.

The saturation feedback v_{fb} in FIGS. 1a and 1b is used as a fault signal. By monitoring the saturation feedback v_{fb}, a failure of a component can be detected and the system can shut down in order to prevent damage or safety hazard. The switch can be slowly shut off in order to prevent damaging it, for example.

The saturation feedback signal can also be coupled with other failures. For example, a failure in the gate driver can also cause an indication of a fault. However, it can be impossible to distinguish one type of failure from another in this manner.

### SUMMARY

An exemplary device for a power semiconductor switch configured to be controlled on the basis of a gate voltage signal driven by a gate driver unit is disclosed, the device comprising: measuring means for generating a saturation voltage signal on the basis of a voltage over the power semiconductor switch; an auxiliary switch connected between a saturation voltage signal line carrying the saturation voltage signal and an output of the gate driver unit driving the gate voltage signal, wherein the auxiliary switch is configured to be controlled to a conductive state or a non-conductive state on the basis of the gate voltage signal; and feedback means for generating a saturation feedback signal on the basis of the saturation voltage signal.

An exemplary method for a semiconductor switch that is controlled on the basis of a gate voltage signal is disclosed, the method comprising: generating a saturation voltage signal on the basis of a voltage over the power semiconductor switch; controlling the saturation voltage signal by using an auxiliary switch connected between a saturation voltage signal line carrying the saturation voltage signal and an output of the gate driver unit driving the gate voltage signal, the auxiliary switch being controlled to a conductive state or a non-conductive state on the basis of the gate voltage signal; and determining a saturation feedback signal on the basis of the saturation voltage signal.

### BRIEF DESCRIPTION OF THE DRAWINGS

In the following the disclosure will be described in greater detail through exemplary embodiments with reference to the attached drawings, in which

FIGS. 1a and 1b show exemplary waveforms of short circuit detection based on a measurement of a collector-emitter voltage accordance with known inplementations;

FIG. 2 shows an exemplary monitoring device in accordance with an exemplary embodiment of the present disclosure;

FIGS. 3a to 3d show exemplary waveforms of the operation of the device as shown in FIG. 2 in accordance with an exemplary embodiment of the present disclosure;

FIG. 4 shows a detailed view of a first monitoring device in accordance with an exemplary embodiment of the present disclosure;

FIG. 5 shows a detailed view of a second monitoring device in accordance with an exemplary embodiment of the present disclosure;

FIG. 6 shows a detailed view of a third monitoring device in accordance with an exemplary embodiment of the present disclosure;

FIG. 7 shows a detailed view of a fourth monitoring device in accordance with an exemplary embodiment of the present disclosure; and

FIGS. 8a to 8f show exemplary waveforms of the device of FIG. 7 in accordance with an exemplary embodiment of the present disclosure.

### DETAILED DESCRIPTION

Exemplary embodiments of the present disclosure is to provide a method and a device for implementing the method so as to alleviate the above-stated disadvantages.

According to an exemplary embodiment disclosed herein, the method can be used for monitoring a semiconductor switch and a gate driver controlling the switch. The power semiconductor switch can be configured to be controlled to a conductive state or a non-conductive state responsive to a gate voltage signal generated by the gate driver unit. The disclosed method can include generating a saturation feedback signal on the basis of a saturation voltage signal. The saturation voltage signal can be responsive to a voltage over the switch so that short circuits during the conducting state of the power semiconductor switch can be detected.

In addition, the saturation voltage signal can also be controlled on the basis of the gate voltage signal. For example, during the non-conductive state, the saturation voltage signal can be responsive to the level of the gate voltage signal. In this manner, the saturation feedback (which is responsive to the saturation voltage) can be used to relay information on the states of the gate voltage signal and the gate driver generating the gate voltage signal. The saturation feedback signal can indicate if a supply voltage used for generating a voltage level driving a switch into the non-conducting state has a voltage level fulfilling the limits set to it.

By combining the non-conductive state information to the conductive state information, the disclosed method is able to give more meaningful fault information than just a short circuit fault. The disclosed method can indicate a broken component in the gate driving circuit. This additional information can be used to detect a failing component even before the power semiconductor switch shows abnormal behaviour. Thus, a warning can be given before a fault leading to a stop in a process occurs.

The disclosed method can be implemented with minimal additional components. As the additional monitoring does not specify adding isolation channels but uses an existing saturation voltage signal, there is no significant price increase.

This document discloses a method for a gate-controlled power semiconductor switch. The power semiconductor switch can be configured to be controlled to a conductive state or a non-conductive state responsive to a gate voltage signal generated by the gate driver unit.

The disclosed method can include generating a saturation voltage signal which is responsive to a voltage over the power semiconductor switch. The saturation voltage signal can be controlled also on the basis of the gate voltage signal. A saturation feedback signal can be determined on the basis of the saturation voltage signal.

The exemplary method described herein can control the saturation voltage on the basis of the operational state of the power semiconductor switch. During the conductive state of the power semiconductor switch, the saturation voltage can be used for detecting short circuits. However, during the non-conductive state, the saturation voltage signal can be responsive to the level of the gate voltage signal. Thus, the saturation voltage signal can be used for diagnosing supply voltages of the gate driver. The resulting saturation signal waveform can then be analysed in order to detect different fault conditions, like a missing positive and/or negative supply voltage. A failing component can be detected even before the switching element shows incorrect behavior. Thus, the disclosed method can produce further diagnostic information in addition to the short circuit information.

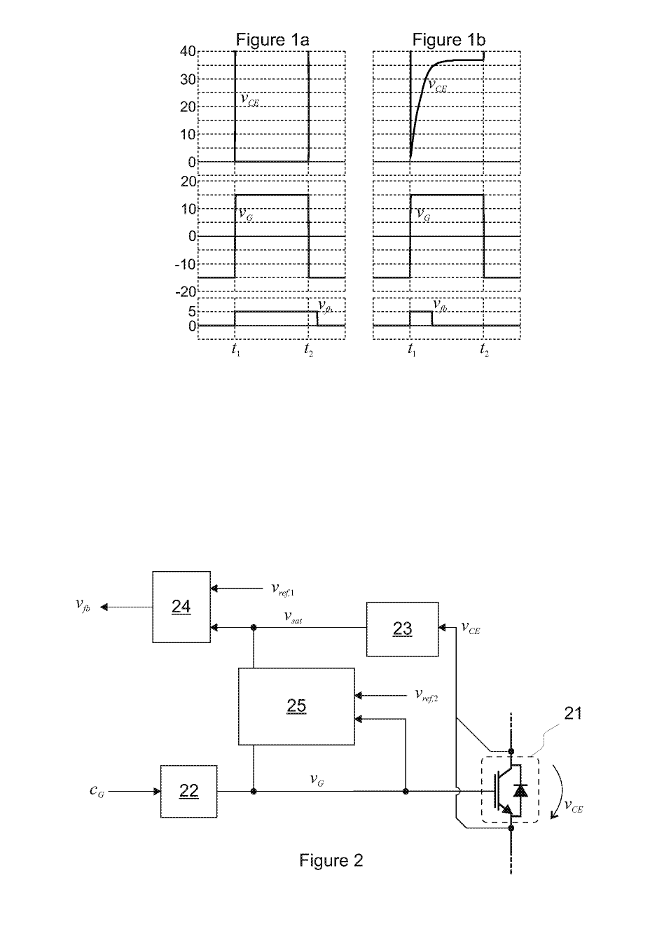

FIG. 2 shows an exemplary monitoring device in accordance with an exemplary embodiment of the present disclosure. In FIG. 2, a power semiconductor switch 21 in the form of an IGBT is controlled by a gate driver 22. In another exemplary embodiment of the present disclosure, the power semiconductor switch can be a MOSFET, for example. The gate driver 22 controls a gate voltage v_{G} on the basis of a control signal c_{G}.

As shown in FIG. 2, the device includes measuring means 23, such as a voltmeter, sensor, or other suitable component as desired, for measuring a voltage v_{CE} over a power semiconductor switch 21. The measuring means 23 generates a saturation voltage vₛₐₜ on the basis of the voltage v_{CE}. Feedback means 24, such as a comparator, isolator, or other suitable component determines a saturation feedback voltage v_{fb} on the basis of a first voltage difference v_{ref,1}−vₛₐₜ, e.g., a voltage difference between the first reference v_{ref,1} and the saturation voltage vₛₐₜ in FIG. 2. For example, the first voltage difference can be compared with a first threshold, and the saturation feedback voltage v_{fb} can be generated on the basis of the comparison.

In FIG. 2, the saturation voltage signal vₛₐₜ can be controlled on the basis of the gate voltage signal v_{G} by using control means 25. During the non-conductive state of the power semiconductor switch 21, the control means 25 can connect an output of the gate driver unit 22 driving the gate voltage signal v_{G} to a saturation voltage signal line carrying the saturation voltage signal vₛₐₜ so that the saturation voltage signal vₛₐₜ is responsive to the gate driver 22 output.

For example, the control means 25, such as a control circuit, integrated circuit, or other suitable control device, can include an auxiliary switch connected between a saturation voltage signal line carrying the saturation voltage signal vₛₐₜ and an output of the gate driver unit 22 driving the gate voltage signal v_{G}. The auxiliary switch can be configured to be controlled to a conductive state or a non-conductive state on the basis of the level of the gate voltage signal. The control means 25 can control the auxiliary switch on the basis of a second voltage difference v_{ref,2}−v_{G}, e.g., a voltage difference between the gate voltage signal v_{G} and the second reference v_{ref,2}. If the difference exceeds a second threshold, the auxiliary switch is driven into the conductive state.

Under normal operation, the gate driver 22 drives the gate voltage to a positive voltage during the conductive state of the power semiconductor switch 21. The difference between the second reference signal v_{ref,2} and the gate voltage signal v_{G} does not exceed the set threshold, and the control means 25 control the auxiliary switch to the non-conductive state. Thus, only the measuring means 23 drive the saturation voltage signal vₛₐₜ. The saturation voltage signal vₛₐₜ is responsive to the voltage v_{CE} over the power semiconductor switch 21.

During the non-conductive state of the power semiconductor switch 21, however, the gate voltage v_{G} is negative, and the difference between the second reference signal v_{ref,2} and the gate voltage signal v_{G} exceeds the set limit. The control means 25 turn the auxiliary switch on, and the saturation voltage signal vₛₐₜ becomes responsive to the gate voltage signal v_{G}.

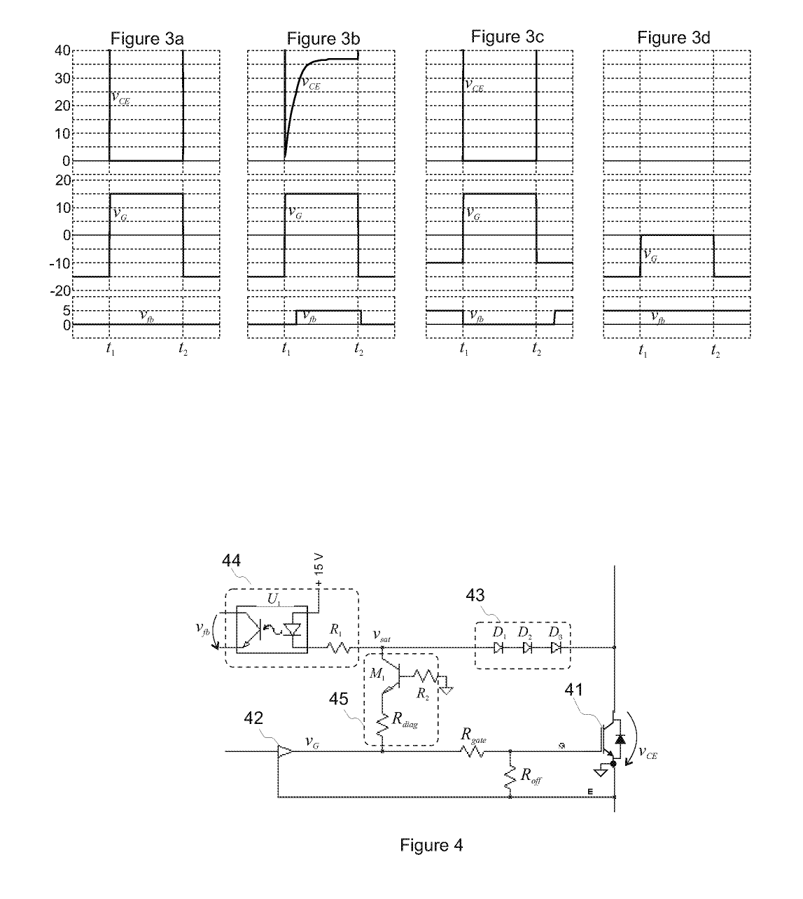

FIGS. 3a to 3d show exemplary waveforms of the operation of the device as shown in FIG. 2 in accordance with an exemplary embodiment of the present disclosure. In FIGS. 3a to 3d, the IGBT 21 is configured to be controlled by a gate voltage v_{G} that alternates between voltage levels −15V and 15 V. These voltage levels are represented with respect to a voltage potential of the emitter of the power semiconductor switch 21. The emitter voltage potential acting as a ground potential can be obtained from an auxiliary emitter of the IGBT 21, for example. The second reference voltage v_{ref,2} is tied to the emitter voltage potential of the power semiconductor switch.

The saturation feedback signal v_{fb} in FIGS. 3a to 3d is a two-level signal having a 5 V high level and a 0 V low level. The saturation feedback signal v_{fb} is generated on the basis of the first voltage difference v_{ref,1}−vₛₐₜ. A low saturation feedback signal v_{fb} is generated if the first voltage difference exceeds the first threshold. If not, a high saturation feedback signal v_{fb} is generated instead. The first reference v_{ref,1} is 15 V in FIGS. 3a to 3d.

FIG. 3a shows the waveforms during normal operation. The gate voltage signal v_{G} at a normal non-conducting state level is at −15 V. The second voltage difference v_{ref,2}−v_{G} is higher than the second threshold, so the auxiliary switch is set to a conducting state and the gate driver 22 pulls the saturation voltage vₛₐₜ down. As a result, the first voltage difference exceeds the first threshold and, thus, the saturation feedback is initially low.

At instant t₁, the gate voltage v_{G} switches from −15 V to 15 V, and the power semiconductor switch 21 turns on. The second voltage difference v_{ref,2}−v_{G} is no longer higher than the second threshold, and thus, the gate driver 22 does not drive the saturation voltage vₛₐₜ. Instead, the saturation voltage vₛₐₜ is driven by the measuring means 23. The saturation voltage vₛₐₜ, which in this case is the collector-emitter voltage, drops to a near-zero value. The first voltage difference v_{ref,1}−vₛₐₜ exceeds the first threshold, and thus, the saturation feedback v_{fb} remains low.

At instant t₂ in FIG. 3a, the power semiconductor switch 21 turns off as the gate voltage switches back to −15 V. The difference v_{ref,2}−v_{G} rises above the second threshold, and the control means 25 turn the auxiliary switch on. Thus, the gate driver 22 pulls the saturation voltage vₛₐₜ down, and the saturation feedback signal v_{fb} remains low.

FIG. 3b shows waveforms during a short circuit. Initially, the second voltage difference v_{ref,2}−v_{G} exceeds the second threshold, and the gate driver 22 drives the saturation voltage vₛₐₜ. Thus, the saturation feedback is initially low.

At instant t₁, the gate voltage rises from −15 V to 15 V, and the power semiconductor switch 21 turns on. The saturation voltage vₛₐₜ is driven by the measuring means 23 and drops to a near-zero value. The first voltage difference v_{ref,1}−vₛₐₜ is higher than the first threshold, and the saturation feedback v_{fb} remains low. However, because of the short circuit current, the saturation voltage vₛₐₜ starts to rise again. The second voltage difference v_{ref,1}−vₛₐₜ decreases until it is below the first threshold, and after a small delay, the saturation feedback v_{fb} signal is set to the high level.

At instant t₂ in FIG. 3b, the gate voltage switches back to −15 V. The power semiconductor switch 21 turns off, and the gate driver 22 drives the saturation voltage vₛₐₜ. The first voltage difference v_{ref,1}−vₛₐₜ again exceeds the first threshold, and the saturation feedback signal v_{fb} changes to the low level.

FIG. 3c shows waveforms during an abnormal negative supply voltage. In FIG. 3c, the negative level of the gate voltage v_{G} is −10 V. The second voltage difference v_{ref,2}−v_{G} is not higher than the second threshold, and thus, the gate driver 22 does not drive the saturation voltage vₛₐₜ. The measuring means 23 drive the saturation voltage vₛₐₜ to the level of the voltage over the power semiconductor switch 21. Therefore, the voltage difference v_{ref,1}−vₛₐₜ does not exceed the first threshold, and the saturation feedback is initially high.

In accordance with another exemplary embodiment, the device can be configured such that a −10 V second voltage difference v_{ref,2}−v_{G} exceeds the second threshold and the gate driver 22 drives the saturation voltage vₛₐₜ. However, the low negative of the gate voltage v_{G} generates a saturation voltage vₛₐₜ that is too low for a voltage difference v_{ref,1}−vₛₐₜ that would exceed the first threshold. As a result, the voltage difference v_{ref,1}−vₛₐₜ does not exceed the first threshold, and the saturation feedback is initially high.

At instant t₁, the gate voltage v_{G} switches from −10 V to 15 V, and the power semiconductor switch 21 turns on. The second voltage difference v_{ref,2}−v_{G} is not higher than the second threshold, and thus, the gate driver 22 does not drive the saturation voltage vₛₐₜ. The saturation voltage vₛₐₜ is driven by the measuring means 23. As there is no short circuit, the saturation voltage vₛₐₜ drops to a near-zero value. The voltage difference v_{ref,1}−vₛₐₜ is higher than the first threshold, and thus, the saturation feedback v_{fb} is set to the low level.

At instant t₂ in FIG. 3c, the gate voltage switches back to −10 V. The power semiconductor switch 21 turns off. The second voltage difference v_{ref,2}−v_{G} is not sufficiently high to set the auxiliary switch to a conductive state. Thus, the gate driver 22 does not drive the saturation voltage vₛₐₜ. The measuring means 23 drive the saturation voltage vₛₐₜ to the level of the voltage over the power semiconductor switch 21, and thus, the saturation feedback v_{fb} is again set to the high level.

FIG. 3d shows waveforms during a detection of an abnormal positive supply voltage level. Because of the abnormal positive supply voltage, the level of the gate voltage v_{G} driving the power semiconductor switch 21 to a conductive state is 0 V. The negative supply voltage is normal, and the second voltage difference v_{ref,2}−v_{G} is higher than the second threshold. Thus, the gate driver 22 drives the saturation voltage vₛₐₜ. However, because the first reference v_{ref,1} is at an abnormally low level, the first voltage difference v_{ref,1}−vₛₐₜ does not exceed the first threshold. Thus, the saturation feedback is initially at the high level.

At instant t₁, the gate voltage v_{G} switches from −15 V to 0 V, which is not enough to turn the power semiconductor switch 21 on. The second voltage difference v_{ref,2}−v_{G} is not higher than the second threshold, and thus, the gate driver 22 does not drive the saturation voltage vₛₐₜ. Instead, the saturation voltage vₛₐₜ is driven by the measuring means 23. As the power semiconductor switch 21 is not turned on, the saturation voltage vₛₐₜ does not drop. Thus, the first voltage difference v_{ref,1}−vₛₐₜ is lower that the first threshold, and the saturation feedback v_{fb} remains at the high level.

At instant t₂ in FIG. 3d, the gate voltage switches back to −15 V. The power semiconductor switch 21 turns off. The second voltage difference v_{ref,2}−v_{G} sets the auxiliary switch 25 to the conductive state. The gate driver 22 pulls the saturation voltage vₛₐₜ down. However, because of the abnormally low level of the first reference v_{ref,1}, the first voltage difference v_{ref,1}−vₛₐₜ does not exceed the first threshold. Thus, the saturation feedback remains at the high level.

Each of FIGS. 3a to 3d shows a different saturation feedback signal waveform. The waveforms can be used for distinguishing different fault conditions from each other. For example, in FIGS. 3c and 3d, a high saturation feedback signal during the non-conductive state of the power semiconductor switch can be used for indicating a faulty voltage supply in the gate driver.

According to an exemplary embodiment of the present disclosure, a device for a power semiconductor switch is configured to be controlled to a conductive state or a non-conductive state on the basis of a gate voltage signal. The gate voltage signal can be generated by a gate driver unit.

The device can include measuring means, such as a voltmeter, resistor, or other suitable measuring component or device, for generating a saturation voltage signal on the basis of a voltage over the power semiconductor switch, and feedback means, such as a comparator or isolator, for generating a saturation feedback signal on the basis of the saturation voltage signal. The saturation feedback signal can be determined on the basis of a first voltage difference, e.g., a voltage difference between a first reference voltage and the saturation voltage signal. The first voltage difference can be compared with a first threshold, and the saturation feedback signal can be generated on the basis of the comparison, for example.

The device can also include an auxiliary switch connected between a saturation voltage signal line carrying the saturation voltage signal and an output of the gate driver unit driving the gate voltage signal, wherein the auxiliary switch can be configured to be controlled to a conductive state or a non-conductive state on the basis of the gate voltage signal. For example, the device can include means, such as a resistor, for generating a voltage between the gate and source (or base and emitter) of the auxiliary switch on the basis of the gate voltage signal.

The auxiliary switch can be configured to be controlled on the basis of a second voltage difference, e.g., a voltage difference between a second reference signal and the gate voltage signal. The second voltage difference can be compared with a second threshold. The second reference voltage can be the emitter voltage potential measured from an auxiliary emitter of the power semiconductor switch, for example. Thus, the second threshold can be the threshold voltage of the auxiliary switch. If the power semiconductor switch is a MOSFET, the second reference voltage can be the source voltage potential, for example.

FIG. 4 shows a detailed view of a first monitoring device in accordance with an exemplary embodiment of the present disclosure. As shown in FIG. 4, the power semiconductor switch is an IGBT 41. The IGBT 41 is controlled by a gate driver 42 through a gate resistor R_{gate}. A pull-down resistor R_{off} is connected between the gate and the emitter of the power semiconductor switch 41.

The saturation feedback v_{fb} is generated on the basis of a saturation voltage signal vₛₐₜ by a saturation feedback circuitry that includes measuring means 43 and feedback means 44.

The measuring means 43 are formed by at least one diode connected to a collector (or drain) terminal of the power semiconductor switch for generating the saturation voltage signal vₛₐₜ. As shown in FIG. 4, the monitoring device includes three diodes D₁ to D₃ are used. The diodes can be high voltage PN diodes.

The diodes D₁ to D₃ allow a saturation voltage line carrying the saturation voltage vₛₐₜ to be driven to the collector potential of the power semiconductor switch when the collector potential is below the saturation voltage vₛₐₜ, but they block a flow of current from said collector or drain terminal to the saturation voltage signal vₛₐₜ. Thus, the monitoring device is protected against a high collector-emitter voltage of the power semiconductor switch 41 during the non-conductive state.

The feedback means can include an isolator for providing a galvanic isolation between the saturation feedback signal and the saturation voltage signal. The isolator can be configured to produce the saturation feedback signal on the basis of the difference between the saturation voltage signal and the first reference voltage signal.

For example, in FIG. 4 the feedback means 44 includes a resistor R₁ and an isolator U₁ in the form of an optocoupler. A resistance between two output terminals of the isolator U₁ is responsive to a current between two input terminals. The inputs can be galvanically isolated from the outputs. The saturation feedback signal is read between the two output terminals of the isolator.

In FIG. 4, one of the input terminals is connected to the saturation voltage signal through the resistor R₁. The other input terminal is connected to a first reference voltage signal v_{ref,1} which in FIG. 4 is a 15 V positive supply voltage supplying the gate driver unit 42. The emitter potential (or the source potential, if a power MOSFET is being used) of the power semiconductor switch acts as a ground potential for the positive supply voltage.

The current between the input terminals of the isolator U₁ is responsive to a first voltage difference over the series connection of the isolator U₁ and the resistor R₁. The first voltage difference also represents the voltage difference v_{ref,1}−vₛₐₜ between the first reference v_{ref,1} and the saturation voltage vₛₐₜ. When the first voltage difference v_{ref,1}−vₛₐₜ rises above a first threshold, the current through the inputs of the isolator U₁ rises above a threshold, and the resistance between the outputs drops significantly. The saturation feedback signal v_{fb} can be generated by connecting the output in series with a pull-up resistor, for example. This generates an active-low indicator signal, e.g., the output voltage is pulled down when the voltage difference between the input terminals exceeds the set limit.

In FIG. 4, the auxiliary switch M₁ is a NPN-type BJT. The saturation voltage signal line is connected to a collector terminal of the auxiliary switch M₁. The output v_{G} of the gate driver 42 unit is connected to an emitter terminal of the auxiliary switch M₁ through a resistor R_{diag}. A base terminal of the auxiliary switch M₁ is connected to a second reference voltage line through a resistor R₂. The second reference voltage line carries the second reference voltage v_{ref,2} and is connected to an auxiliary emitter of the IGBT 41. The operational state of the auxiliary switch M₁ can be controlled on the basis of a second voltage difference v_{ref,2}−v_{G} between the second reference voltage v_{ref,2} and the gate driver output v_{G}. When the second voltage difference v_{ref,2}−v_{G} rises, the base-emitter voltage of the auxiliary switch M₁ exceeds its threshold, and the auxiliary switch starts to conduct.

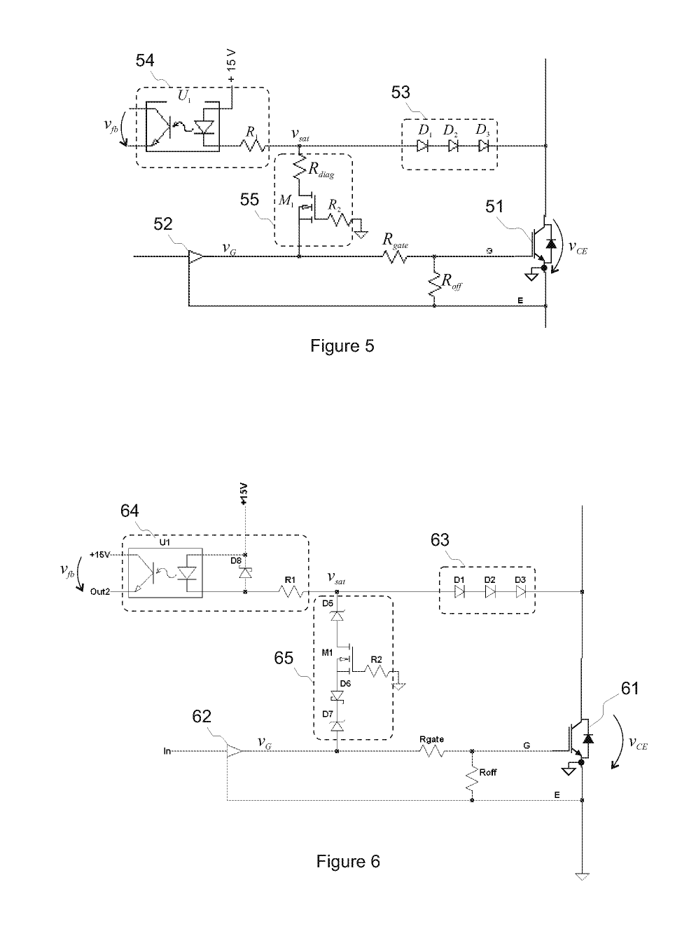

FIG. 5 shows a detailed view of a second monitoring device in accordance with an exemplary embodiment of the present disclosure. As shown in FIG. 5, an IGBT 51 is controlled by a gate driver 52. Three high voltage PN diodes D₁ to D₃ form measuring means 53. The diodes D₁ to D₃ generate the saturation voltage signal. Feedback means 54 includes an optocoupler U₁ and a resistor R₁.

The auxiliary switch M₁ is a logic-level N-channel MOSFET. The saturation voltage signal line is connected to a drain terminal of the auxiliary switch M₁ through a resistor R_{diag}. The output of the gate driver unit 52 is connected to a source terminal of the auxiliary switch, and the second reference voltage line is connected to a gate terminal of the auxiliary switch through a resistor R₂.

FIG. 6 shows a detailed view of a third monitoring device in accordance with an exemplary embodiment of the present disclosure. As shown in FIG. 6, an IGBT 61 is controlled by a gate driver 62. Three high voltage PN diodes D₁ to D₃ form measuring means 63. The diodes D₁ to D₃ generate the saturation voltage signal. Feedback means 64 include an optocoupler U₁, a resistor R₁, and a Schottky diode D₈ connected between the inputs of the optocoupler U₁. The first reference voltage signal for the feedback means 64 is the positive supply voltage supplying the gate driver unit with 15 V.

In FIG. 6, the saturation voltage signal line is connected to a drain terminal of the auxiliary switch M₁ through a zener diode D₅. The zener diode D₅ is connected such that it blocks a flow of current from the saturation voltage signal line to the drain terminal until its zener voltage V_{D5,z} is exceeded. The output of the gate driver unit 62 is connected to a source terminal of the auxiliary switch M₁ through a series-connection of a Schottky diode D₆ and a zener diode D₇. The Schottky diode D₆ is connected such that it blocks a flow of current from the gate driver output to the source terminal. The zener diode D₇ is connected such that it blocks a flow of current from the source terminal to gate driver output until its zener voltage V_{D7,z} is exceeded. A second reference voltage line is connected to the emitter potential of the power semiconductor switch. The second reference voltage line is connected to a gate terminal of the auxiliary switch through a resistor R₂.

The operation of the embodiment of FIG. 6 is explained through the following examples and using exemplary component values.

According to a first example, a resistance of the resistor R₁ can be approximately 400Ω, for example; a forward voltage V_{U1,f} for the optocoupler U₁ while in an on-state can be approximately 1.5 V; a threshold current I_{U1,th} for the optocoupler can be approximately 1.5 mA; Thus, a first threshold V_{th,1} for a first voltage difference v_{ref,1}−vₛₐₜ, e.g., for a voltage difference between the first reference v_{ref,1} and the saturation voltage vₛₐₜ can be calculated as follows:

V_{th,1}=(R₁·I_{U1,th})+V_{U1,f}≈2 V. (1)

The zener voltage V_{D7,z} of the zener diode D₇ can be 10 V, for example; a forward voltage V_{D6,f} of the Schottky diode D₆ can be 0.3V; and a threshold voltage V_{M1,th} for the voltage between the gate and source of the auxiliary switch M₁ can be approximately 2 V. Above the threshold voltage V_{M1,th}, the auxiliary switch M₁ is in conductive state. Thus, a second threshold V_{th,2} for the second voltage difference, e.g., for the voltage difference between a second reference signal v_{ref,2} and the gate voltage signal v_{G} becomes:

V_{th,2}=V_{M1,th}+V_{D6,f}+V_{D7,z}≈12 V. (2)

The voltage level of the second reference signal v_{ref,2} can be set by adjusting the zener voltage V_{D7,z}.

During the non-conductive state under normal operation, the gate driver 62 outputs an off-state gate voltage v_{G,off} in order to drive the power semiconductor switch 61 to a non-conducting state. The collector-emitter voltage of the power semiconductor switch is at a high level. In FIG. 6, the off-state gate voltage v_{G,off} can be −15 V. Thus, the second voltage difference v_{ref,2}−v_{G,off} (=0 V−(−15 V)=15 V) exceeds the second threshold V_{th,2}. The voltage between the gate and the source of the auxiliary switch M₁ is approximately 5 V, which is enough to turn the auxiliary switch M₁ on. A zener voltage V_{D5,Z} of the zener diode D₅ can be 14 V. The gate driver 62 drives the saturation voltage vₛₐₜ, for which the following value can be calculated as:

vₛₐₜ=v_{G,off}+V_{D7,z}+V_{D6,f}+V_{D5,z}=9 V. (3)

The first voltage difference v_{ref,1}−vₛₐₜ (=15 V−9 V=6 V) is greater than the first threshold voltage V_{th,1}, and thus, the feedback signal is driven low.

When the power semiconductor switch 61 turns on during normal operation, the second voltage difference, now represented by a voltage difference between the second reference v_{ref,2} and a conducting state gate voltage v_{G,on}, no longer exceeds the second threshold V_{th,2}:

v_{ref,2}−v_{G,on}(=0 V−15 V)<V_{th,}2. (4)

As a result, the gate-source voltage of the auxiliary switch M₁ falls under its threshold voltage V_{M1,th}, and the auxiliary switch M₁ is turned off. Therefore, the saturation voltage vₛₐₜ is driven by the diodes D₁ to D₃. Under normal operation, the voltage over the power semiconductor switch is so low that the resulting voltage difference v_{ref,1}−vₛₐₜ exceeds the first reference v_{ref,1}. The current through the inputs of the optocoupler U₁ is higher than the threshold current I_{U1,th}, and the optocoupler U₁ output is set low.

However, if a short circuit occurs, the collector-emitter voltage of the power semiconductor switch 61 rises, and the diodes D₁ to D₃ are not able to pull the saturation voltage vₛₐₜ down. As a result, the resulting voltage difference v_{ref,1}−vₛₐₜ does not exceed the first threshold voltage V_{th,1}, and a short circuit is indicated by a high signal.

In addition to detecting short circuits, the embodiment of FIG. 6 is able to detect an abnormal gate voltage levels during the non-conductive state of the power semiconductor switch 61. For example, if the off-state gate voltage v_{G,off} is abnormally low, e.g., the second voltage difference v_{ref,2}−v_{G,off} is below the second threshold V_{th,2}, the gate-source voltage of the auxiliary switch M₁ falls under its threshold voltage V_{M1,th}, and the auxiliary switch M₁ is turned off. In FIG. 6, the second threshold V_{th,2} is 12 V, so off-state voltage levels of the gate voltage v_{G,off} which are less negative than −12 V will cause the auxiliary switch M₁ to turn off. The collector-emitter voltage of the power semiconductor switch 61 is at a high, non-conductive state level, and the diodes D₁ to D₃ are not able to pull the saturation voltage vₛₐₜ to a low voltage level. The resulting voltage difference v_{ref,1}−vₛₐₜ does not exceed the first reference V_{ref,1}, and an abnormal gate voltage is indicated by a high feedback signal.

Because the positive supply voltage of 15V serves as the first reference v_{ref,1}, the exemplary embodiment of FIG. 6 can also detect abnormalities in the positive supply voltage during the non-conductive state of the power semiconductor switch 61.

During the non-conducting state, the saturation voltage vₛₐₜ can be 9 V (see Equation 4). In order for the first voltage difference v_{ref,1}−vₛₐₜ to exceed the first threshold voltage V_{th,1} (=2V, Equation 1), the first voltage reference v_{ref,1}, in this case the positive supply voltage, has to be 11 V or more. If the positive supply voltage is less than 11 V, the first voltage difference v_{ref,1}−vₛₐₜ is less than the first threshold voltage V_{th,1}, the current through the optocoupler is lower than the threshold current I_{U1,th} and the optocoupler U₁ output is set to the high level. The threshold level for triggering a low positive supply voltage can be controlled by adjusting the zener voltage V_{D5,Z} of the zener diode D₅. Similar voltage drop of the negative supply voltage can give similar results.

The above exemplary component values show one implementation of the embodiment of FIG. 6. However, the embodiment is not limited to the values given in this document, but other values can also be used.

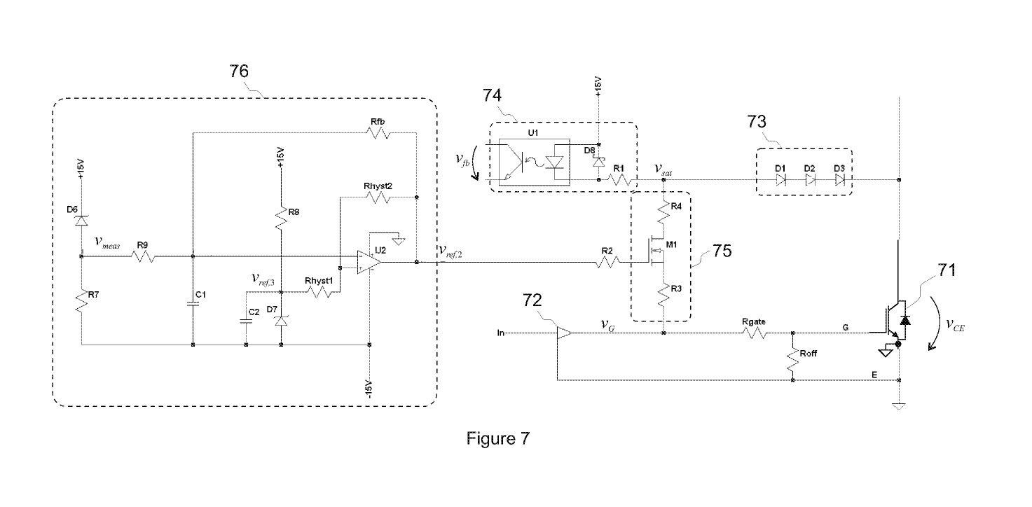

FIG. 7 shows a detailed view of a fourth monitoring device in accordance with an exemplary embodiment of the present disclosure. As shown in FIG. 7, an IGBT 71 is controlled by a gate driver 72. Three high voltage PN diodes D₁ to D₃ form measuring means 73 and generate the saturation voltage signal. Feedback means 74 includes an optocoupler U₁, a resistor R₁, and a Schottky diode D₈. The first reference voltage signal v_{ref,1} for the feedback means 74 is a positive supply voltage supplying the gate driver unit with 15 V. A negative supply voltage for the gate driver unit is −15 V. The emitter potential of the IGBT 71 serves as the ground potential for the supply voltages. A series connection of a resistor R₄, an auxiliary switch M₁, and a resistor R₃ form control means 75. The auxiliary switch M₁ is controlled on the basis of a difference between a second reference signal v_{ref,2} and the gate voltage signal v_{G}. The output of the gate driver unit 72 is connected to a source terminal of the auxiliary switch M₁ through the resistor R₃. The saturation voltage signal line is connected to a drain terminal of the auxiliary switch M₁ through the resistor R₄.

The second reference signal v_{ref,2} is generated by reference voltage generating means 76, including discrete circuit components, an integrated circuit, or other suitable components or devices as desired which are connected to a gate terminal of the auxiliary switch M₁ through a resistor R₂.

The reference voltage generating means 76 can be configured to modulate the second reference signal v_{ref,2} in order to modulate the feedback signal v_{fb} during the non-conductive state of the power semiconductor switch 71 such that the modulation of the feedback signal v_{fb} is responsive to the levels of the positive supply voltage and/or the negative supply voltage. For example, the switching frequency and/or duty cycle of the modulation of the feedback signal v_{fb} can be configured to be responsive to one or both of the supply voltages.

In FIG. 7, the reference voltage generating means 76 generates a pulse-width-modulated second reference signal v_{ref,2} that, in turn, produces a pulse-width-modulated feedback signal v_{fb} during the non-conductive state of the IGBT 71. The switching frequency and duty cycle of the feedback signal v_{fb} are responsive to the levels of the positive supply voltage and the negative supply voltage. The reference voltage generating means 76 includes a comparator, a voltage reference, a voltage level shifter, and an RC circuit.

A resistor R₈, a zener diode D₇, and a capacitor C₂ are used to generate a third reference voltage v_{ref,3}.

The RC circuit is formed by resistors R₉ and R_{fb}, and a capacitor C₁. The comparator is formed by a comparator circuit U₂ with resistors R_{hyst,1} and R_{hyst,2} generating hysteresis. The comparator compares the voltage over the capacitor C₁ of the RC circuit with the voltage reference. The comparator output is fed back to the RC circuit through the resistor R_{fb}. As a result, a PWM signal is generated. The comparator output is used as the second reference signal v_{ref,2}.

The voltage level shifter in FIG. 7 is formed by a zener diode D₆ and a resistor R₇. The level shifter measures the voltage difference between the positive supply voltage and the negative supply voltage. The level shifter then reduces a fixed voltage magnitude from the difference by using the zener diode D₆. A resulting voltage difference vₘₑₐₛ can be measured over the resistor R₇.

The voltage difference vₘₑₐₛ is fed to the RC circuit through the resistor R₉. Thus, the voltage over the capacitor is responsive to the voltage difference vₘₑₐₛ. A change in a level or levels of the gate driver supplies causes a change in the output frequency and the duty cycle of the generated PWM signal. With a low voltage difference vₘₑₐₛ, the duty cycle and the modulation frequency are small, and vice versa.

In the following example, the operation of the exemplary device shown in FIG. 7 is explained using exemplary component values.

The resistance of the resistor R₈ can be 11 kΩ; a zener voltage of the zener diode D₇ can be 9 V; and a capacitance of the capacitor C₂ can be 1 μF.

The comparator circuit U₂ can be supplied by 0 V (e.g., power semiconductor switch emitter potential) and −15 V. Thus, the output of the comparator circuit can alternate between 0 V and −15 V.

The resistors R_{hyst,1} and R_{hyst,2} can have values 1 kΩ and 510 kΩ, respectively; a capacitance of the capacitor C₁ can be 100 nF; and a resistance of the resistor R_{fb} can be 7 kΩ. The combination of an RC time constant and the hysteresis of the comparator gives a base modulation frequency of approximately 90 kHz.

A voltage difference between the positive supply voltage (15 V) and the negative supply voltage (−15 V) can be in the neighborhood of a level of 30 V under normal operating conditions, for example. If the level of one or both supply voltages is too high (for example, the positive supply >15 V or the negative supply <−15 V), the difference is above 30 V. If the level of one or both supply voltages is too low (for example, the positive supply <15 V or the negative supply >−15 V), the difference is below 30 V.

For example, in FIG. 7 the zener diode D₆ has a zener voltage of 20 V. Thus, the resulting voltage difference vₘₑₐₛ is in the neighborhood of 10 V.

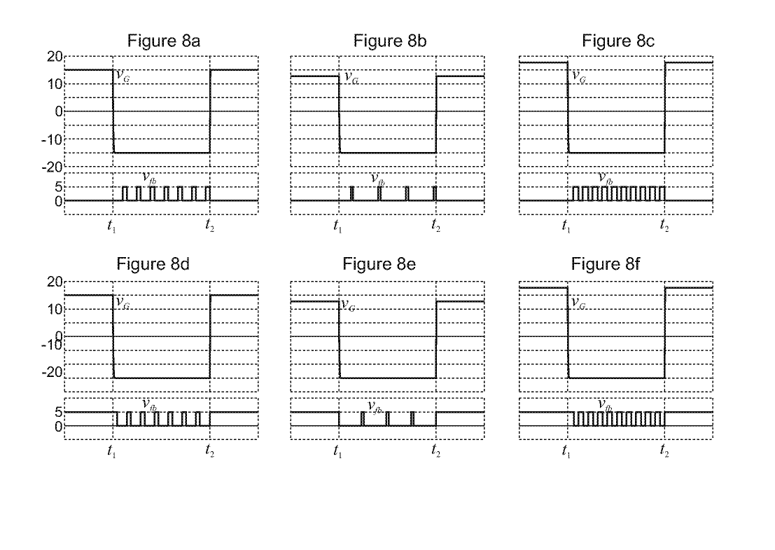

FIGS. 8a to 8f show exemplary waveforms of the device of FIG. 7 in accordance with an exemplary embodiment of the present disclosure. In FIGS. 8a to 8f, period t₁ to t₂ shows a non-conducting state of the power semiconductor switch.

FIGS. 8a to 8c show waveforms where the IGBT 71 switches correctly and no short circuit is detected.

FIG. 8a shows operation when the supply voltages for the gate driver are within set operating ranges. During the conductive state of the IGBT 71, the feedback signal acts as a short circuit detector. No short circuit is detected and thus, the feedback signal is low. During the non-conductive state of the IGBT 71, the feedback signal is modulated. The switching frequency and duty cycle of the modulation are responsive to the levels of the positive supply voltage and the negative supply voltage.

FIG. 8b shows waveforms of operation when the positive supply voltage is too small. The switching frequency and the duty cycle of the pulse-shaped feedback signal are now smaller. A too small negative supply voltage induces a corresponding waveform.

FIG. 8c shows waveforms of operation when the positive supply voltage is too high. The switching frequency and the duty cycle of the pulse-shaped feedback signal are now higher. A too large negative supply voltage (e.g., more negative voltage) induces a corresponding waveform.

FIGS. 8d to 8f show waveforms where the collector of the IGBT 71 is disconnected and no current flows through it. The collector-emitter voltage remains at a high level throughout the switching cycle.

FIG. 8d shows operation when the supply voltages for the gate driver are within set operating ranges. During the conductive state of the IGBT 71, the feedback signal acts as a short circuit detector. However, because the collector is disconnected and no current flows through the IGBT 71, the collector-emitter voltage of the IGBT 71 remains at a high level. Thus, the feedback signal is high. During the non-conductive state of the IGBT 71, the feedback signal is modulated.

FIG. 8e shows waveforms of operation when the positive supply voltage is too small. The switching frequency and the duty cycle of the pulse-shaped feedback signal are now smaller. A too small negative supply voltage induces a corresponding waveform. During the conductive state of the IGBT 71, the feedback signal is high.

FIG. 8f shows waveforms of operation when the positive supply voltage is too high. The switching frequency and the duty cycle of the pulse-shaped feedback signal are now higher. A too large negative supply voltage (e.g., more negative voltage) induces a corresponding waveform. During the conductive state of the IGBT 71, the feedback signal is high.

With this information, a voltage feedback can be generated. On the basis of the voltage feedback, the supply voltages can be adjusted in order to achieve correct gate driver output voltage levels. Also, voltage drops during high frequency switching of the power semiconductor switch can be measured, or a faulty gate driver power supply can be detected.

Thus, it will be appreciated by those skilled in the art that the present invention can be embodied in other specific forms without departing from the spirit or essential characteristics thereof. The presently disclosed exemplary embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. A device for a power semiconductor switch configured to be controlled on the basis of a gate voltage signal driven by a gate driver unit, the device comprising:
measuring means for generating a saturation voltage signal on the basis of a voltage over the power semiconductor switch;
an auxiliary switch connected between a saturation voltage signal line carrying the saturation voltage signal and an output of the gate driver unit driving the gate voltage signal, wherein the auxiliary switch is configured to be controlled to a conductive state or a non-conductive state on the basis of the gate voltage signal; and
feedback means for generating a saturation feedback signal on the basis of the saturation voltage signal.

2. The device as claimed in claim 1, wherein the device is configured to control the saturation voltage signal on the basis of the operational state of the power semiconductor switch.

3. The device as claimed in claim 2, wherein the saturation feedback signal is determined on the basis of a difference between a first reference voltage and the saturation voltage signal.

4. The device as claimed in claim 1, wherein the saturation feedback signal is determined on the basis of a difference between a first reference voltage and the saturation voltage signal.

5. The device as claimed in claim 1, wherein the auxiliary switch is configured to be controlled to a conductive state or a non-conductive state on the basis of a difference between a second reference signal and the gate voltage signal.

6. The device as claimed in claim 2, wherein the auxiliary switch is configured to be controlled to a conductive state or a non-conductive state on the basis of a difference between a second reference signal and the gate voltage signal.

7. The device as claimed in claim 5, wherein the second reference voltage is the emitter or source voltage potential of the power semiconductor switch.

8. The device as claimed in claim 7, wherein the second reference voltage is measured from an auxiliary emitter of the power semiconductor switch.

9. The device as claimed in claim 7, wherein:
the auxiliary switch is a N-channel FET,
the saturation voltage signal line is connected to a drain terminal of the auxiliary switch through a resistor,
the output of the gate driver unit is connected to a source terminal of the auxiliary switch, and
a second reference voltage line carrying the second reference voltage is connected to a gate terminal of the auxiliary switch through a resistor.

10. The device as claimed in claim 7, wherein:
the auxiliary switch is an NPN-type BJT,
the saturation voltage signal line is connected to a collector terminal of the auxiliary switch,
the output of the gate driver unit is connected to an emitter terminal of the auxiliary switch through a resistor, and
a second reference voltage line carrying the second reference voltage is connected to a base terminal of the auxiliary switch through a resistor.

11. The device as claimed in claim 5, comprising:
reference voltage generating means for generating the second reference signal, wherein the reference voltage generating means are configured to modulate the second reference signal in order to modulate the feedback signal during the non-conductive state of the power semiconductor switch such that the modulation of the feedback signal is responsive to the levels of at least one of the positive supply voltage and the negative supply voltage.

12. The device as claimed in claim 1, wherein the measuring means includes at least one diode connected to a collector or drain terminal of the power semiconductor switch for generating the saturation voltage signal, the diode blocking a flow of current from said collector or drain terminal to the saturation voltage signal.

13. The device as claimed in claim 3, wherein the feedback means includes an isolator configured to produce the saturation feedback signal on the basis of the difference between the saturation voltage signal and the first reference voltage signal.

14. The device as claimed in claim 13, wherein the isolator is an optocoupler in which a resistance between two output terminals is responsive to a voltage difference between two input terminals, wherein the inputs are galvanically isolated from the outputs, and wherein one of the input terminals is connected to the saturation voltage signal through a resistor, the other input terminal is connected to the first reference voltage signal, and the saturation feedback signal is read between the two output terminals of the isolator.

15. The device as claimed in claim 8, wherein the first reference voltage signal is a positive supply voltage supplying the gate driver unit.

16. An arrangement comprising:
a power semiconductor switch configured to be controlled on the basis of a gate voltage signal, and a device as claimed in claim 1.

17. A method for a semiconductor switch that is controlled on the basis of a gate voltage signal, the method comprising:
generating a saturation voltage signal on the basis of a voltage over the power semiconductor switch;
controlling the saturation voltage signal by using an auxiliary switch connected between a saturation voltage signal line carrying the saturation voltage signal and an output of the gate driver unit driving the gate voltage signal, the auxiliary switch being controlled to a conductive state or a non-conductive state on the basis of the gate voltage signal; and
determining a saturation feedback signal on the basis of the saturation voltage signal.
